(19) United States
(12) Patent Application Publication
(10) Pub. No.: US 2013/0003279 A1
(43) Pub. Date: Jan. 3, 2013

(54) NOTEBOOK COMPUTER

(75) Inventor: LING LONG, Shenzhen City (CN)

(73) Assignees: HON HAI PRECISION INDUSTRY CO., LTD., Tu-Cheng (TW); HONG FU JIN PRECISION INDUSTRY (ShenZhen) CO., LTD., Shenzhen City (CN)

(21) Appl. No.: 13/191,454

(22) Filed: Jul. 27, 2011

(30) Foreign Application Priority Data
Jun. 28, 2011 (CN) 201110177069.8

(51) Int. Cl. H05K 7/00

(52) U.S. Cl. 361/679.09

(57) ABSTRACT

A notebook computer includes a base, a cover rotatably connected to a rear side of the base, and a keyboard slidably mounted to the base. The keyboard includes a mounting portion disposed on a top of the base, and a supporting portion extending downwards from a front side of the mounting portion.

### BACKGROUND

1. Technical Field

The present disclosure relates to a notebook computer.

2. Description of Related Art

Notebook computers include a base, a screen, and a keyboard fixed to the base. In use, the notebook computer should be positioned so in such a way that users can view the screen comfortably. However, a notebook so positioned may not allow for comfortable use of the keyboard.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIGS. 1 and 2 are isometric views of an exemplary embodiment of a notebook computer in two working states.

### DETAILED DESCRIPTION

The present disclosure, including the accompanying drawings, is illustrated by way of examples and not by way of limitation. It should be noted that references to “an” or “one” embodiment in this disclosure are not necessarily to the same embodiment, and such references mean at least one.

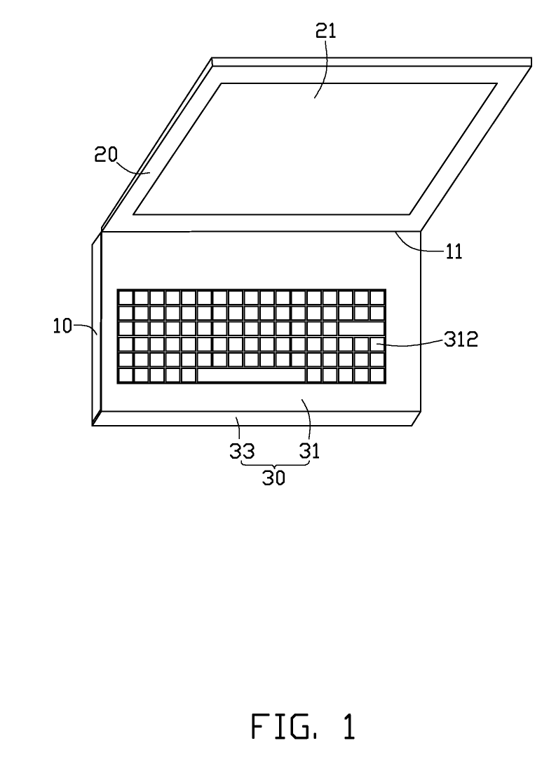

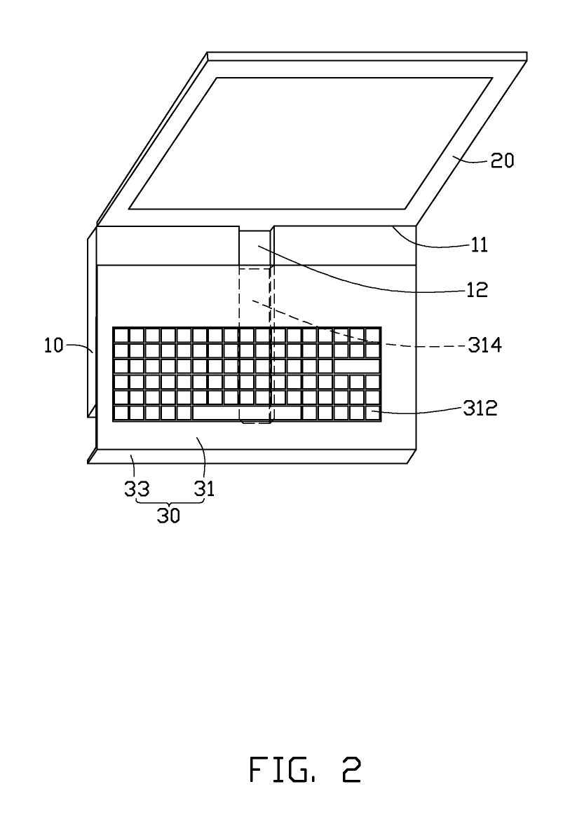

Referring to FIGS. 1 and 2, an exemplary embodiment of a notebook computer includes a base 10, a cover 20 rotatably connected to a rear side 11 of the base 10, and a keyboard 10 slidably mounted to the base 10. A screen 21 is mounted in the cover 20.

A sliding slot 12 is defined in a top of the base 10. The sliding slot 12 extends from, and is perpendicular to the rear side 11.

The keyboard 30 includes a mounting portion 31 disposed on the top of the base 10, and a supporting portion 33 perpendicularly extending from a side opposite the screen 21 of the mounting portion 31. A number of keys 312 are mounted to a top the mounting portion 31. A rail 314 protrudes from a bottom of the mounting portion 31, and is slidably received in the sliding slot 12. A height of the supporting portion 33 of the keyboard 30 is substantially equal to a height of the base 10.

In use, the notebook computer is supported on a supporting surface (not shown), such as a worktable or a desk, with the computer and screen 21 oriented so the screen 21 can be viewed comfortably. The keyboard 30 can then be slid relative to the base 10 and the screen 21, until the keys 312 can be operated comfortably. When the keyboard 30 extends beyond the base 10, the supporting portion 33 may rest on the supporting surface to prevent undue stress on the keyboard 30 in a cantilevered position, thereby stabilizing the notebook computer. With the present keyboard 30 a user can have the screen 21 farther away if it is comfortable to do so while having the keyboard 30 within comfortable reach.

It is to be understood, however, that even though numerous characteristics and advantages of the embodiments have been set forth in the foregoing description, together with details of the structure and function of the embodiments, the present disclosure is illustrative only, and changes may be made in details, especially in matters of shape, size, and arrangement of parts within the principles of the embodiments to the full extent indicated by the broad general meaning of the terms in which the appended claims are expressed.

What is claimed is:

1. A notebook computer comprising:
a base;
a cover rotatably connected to a rear side of the base; and
a keyboard slidably mounted to the base, and comprising a mounting portion disposed on a top of the base, and a supporting portion extending downwards from a front side of the mounting portion.

2. The notebook computer of claim 1, wherein the base defines a sliding slot in a top of the base, the sliding slot extends from, and is perpendicular to, the rear side of the base, a rail protrudes from a bottom of the mounting to slidably be received in the sliding slot of the base.

3. The notebook computer of claim 1, wherein a height of the supporting portion is equal to a height of the base.

4. The notebook computer of claim 1, wherein a screen is mounted in the cover.
